(19) United States
(12) Patent Application Publication
(10) Pub. No.: US 2013/0221402 A1
(43) Pub. Date: Aug. 29, 2013

(54) INSULATED GATE BIPOLAR TRANSISTOR

(71) Applicant: KABUSHIKI KAISHA TOSHIBA, (US)

(72) Inventors: Tsuneo OGURA, Kanagawa-Ken (JP); Kazutoshi NAKAMURA, Kanagawa-Ken (JP)

(73) Assignee: KABUSHIKI KAISHA TOSHIBA, Tokyo (JP)

(21) Appl. No.: 13/762,240

(22) Filed: Feb. 7, 2013

(30) Foreign Application Priority Data
Feb. 27, 2012 (JP) 2012-040643
Oct. 12, 2012 (JP) 2012-226749

(51) Int. Cl. H01L 29/739

(52) U.S. Cl. CPC H01L 29/7395
USPC 257/139

(57) ABSTRACT

An insulated gate bipolar transistor includes a first semiconductor layer of a first conductivity type, a first base layer of a second conductivity type, a second base layer of the second conductivity type, a first emitter layer of the first conductivity type, and a second emitter layer of the first conductivity type. The first semiconductor layer has a first surface. A first trench and a second trench extend from the first surface into the first semiconductor layer. The first gate electrode is provided on the first semiconductor layer, on the first base layer, and on the first emitter layer via a first gate insulating film in the first trench. The second gate electrode is provided on the first semiconductor layer, on the second base layer, and on the second emitter layer via a second gate insulating film in the second trench.

### CROSS-REFERENCE TO RELATED APPLICATION

This application is based upon and claims the benefit of priority from the prior Japanese Patent Application No. 2012-040643, filed on Feb. 27, 2012 and No. 2012-226749, filed on Oct. 12, 2012; the entire contents of which are incorporated herein by reference.

### FIELD

Embodiments described herein relate generally to an insulated gate bipolar transistor.

### BACKGROUND

Insulated gate bipolar transistors (IGBTs) are used for switching elements of inverter circuits etc. It is required for the IGBT to have a high breakdown voltage and low ON resistance. However, there is a problem that the ON resistance increases with increasing breakdown voltage. To solve the problem, a trench gate IGBT suitable for miniaturization is used. In the trench gate IGBT, by narrowing the space between trench gates, the channel width can be effectively increased to reduce the ON resistance between collector and emitter. However, an increase in the channel width causes increases in the saturation current, gate charge, gate-emitter capacitance, and gate-collector capacitance, etc. An increase in the saturation current reduces the short-circuit withstand capability of the IGBT. An increase in the gate charge increases the power loss of a gate drive circuit. Increases in the gate-emitter capacitance and gate-collector capacitance reduce the switching speed of the IGBT.

### BRIEF DESCRIPTION OF THE DRAWINGS

FIG. 1 is a schematic cross-sectional view of a main portion of an IGBT according to a first embodiment;

FIG. 2 is a schematic top view of the main portion of the IGBT according to the first embodiment;

FIG. 3 is a schematic cross-sectional view of a main portion of an IGBT of a comparative example;

FIG. 4 is a view of distribution of holes in a current pathway in the IGBT according to the first embodiment and the IGBT of the comparative example;

FIG. 5 shows operation characteristics in the IGBT according to the first embodiment and the IGBT of the comparative example;

FIG. 6 is a schematic top view of a main portion of an IGBT according to a second embodiment;

FIG. 7 is a schematic cross-sectional view of a main portion of the IGBT according to the second embodiment;

FIG. 8 is a schematic top view of a main portion of an IGBT according to a third embodiment;

FIG. 9 is a schematic cross-sectional view of a main portion of the IGBT according to a third embodiment;

FIG. 10 is a schematic top view of a main portion of an IGBT of a modification example of the third embodiment;

FIG. 11 is a schematic top view of a main portion of an IGBT of another modification example of the third embodiment;

FIG. 12 is a schematic top view of a main portion of an IGBT of another modification example of the third embodiment;

FIG. 13 is a schematic cross-sectional view of a main portion of an IGBT according to a fourth embodiment;

FIG. 14 is a schematic perspective view of a main portion of the IGBT according to the fourth embodiment;

FIG. 15 is a schematic cross-sectional view of a main portion of an IGBT according to a fifth embodiment;

FIG. 16 is a schematic perspective view of a main portion of the IGBT according to the fifth embodiment;

FIG. 17 is a schematic cross-sectional view of a main portion of an IGBT according to a sixth embodiment;

FIG. 18 is a schematic perspective view of a main portion of the IGBT according to the sixth embodiment;

FIG. 19 is a schematic cross-sectional view of a main portion of an IGBT according to a seventh embodiment;

FIG. 20 is a schematic perspective view of a main portion of the IGBT according to the seventh embodiment;

FIG. 21 is a schematic cross-sectional view of a main portion of an IGBT according to an eighth embodiment;

FIG. 22 is a schematic cross-sectional view of a main portion of an IGBT according to a ninth embodiment;

FIG. 23 is a schematic cross-sectional view of a main portion of an IGBT according to a tenth embodiment;

FIG. 24 is a schematic cross-sectional view of a main portion of an IGBT according to an eleventh embodiment; and

FIG. 25 is a schematic cross-sectional view of a main portion of an IGBT according to a twelfth embodiment.

### DETAILED DESCRIPTION

An insulated gate bipolar transistor includes a first semiconductor layer of a first conductivity type, a first trench, a second trench, a first base layer of a second conductivity type, a second base layer of a second conductivity type, a first emitter layer of a first conductivity type, a second emitter layer of a first conductivity type, a first gate electrode, a second gate electrode, an interlayer insulating film, a second semiconductor layer of a second conductivity type, a first electrode, and a second electrode.

The first semiconductor layer has a first surface and a second surface on an opposite side to the first surface. The first trench extends from the first surface of the first semiconductor layer into the first semiconductor layer. The second trench extends from the first surface of the first semiconductor layer into the first semiconductor layer and is adjacent to the first trench.

The first base layer is selectively formed on the first surface of the first semiconductor layer between the first trench and the second trench and exposed at a side wall of the first trench. The second base layer is selectively formed on the first surface of the first semiconductor layer between the first trench and the second trench and exposed at a side wall of the second trench.

The first emitter layer is selectively formed on a surface of the first base layer and exposed at the side wall of the first trench. The second emitter layer is selectively formed on a surface of the second base layer, exposed at the side wall of the second trench and adjacent to the first base layer via the first semiconductor layer.

The first gate electrode is provided on the first semiconductor layer, on the first base layer, and on the first emitter layer via a first gate insulating film in the first trench. The second gate electrode is provided on the first semiconductor layer, on the second base layer, and on the second emitter layer via a second gate insulating film in the second trench and electrically connected to the first gate electrode.

The interlayer insulating film is provided on the first gate electrode and on the second gate electrode.

The second semiconductor layer is provided on the second surface of the first semiconductor layer.

The first electrode is electrically connected to the second semiconductor layer. The second electrode is electrically connected to the first base layer, the second base layer, the first emitter layer, and the second emitter layer.

Various embodiments will be described hereinafter with reference to the accompanying drawings. The drawings used in the description of the embodiments are schematic for easier description; and in the actual practice, the configurations, dimensions, magnitude relationships, etc. of the components in the drawings are not necessarily the same as those illustrated in the drawings and may be appropriately altered so far as the effect of the invention is obtained. Although a description is given using the n type as a first conductivity type and the p type as a second conductivity type, the first and second conductivity types may be the respective opposite conductivity types. Although the semiconductor is described using silicon as an example, the embodiments can be applied also to compound semiconductors such as SiC and GaN. Although the insulating film is described using silicon oxide as an example, also other insulators such as silicon nitride and silicon oxynitride may be used. In the case where the n conductivity type is expressed by n⁺, n, and n⁻, it is assumed that the n-type impurity concentration decreases in the order of n⁺, n, n⁻. Similarly, for the p type, it is assumed that the p-type impurity concentration decreases in the order of p⁺, p, p⁻.

### First Embodiment

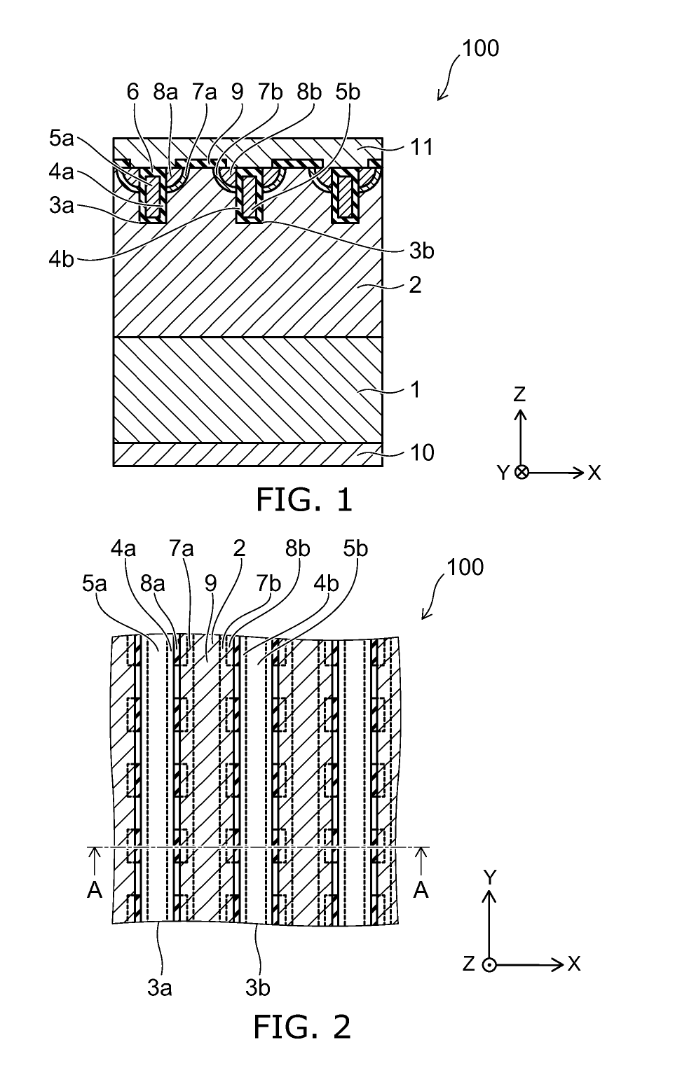

An IGBT 100 according to a first embodiment of the invention will now be described using FIG. 1 and FIG. 2. FIG. 1 is a schematic cross-sectional view of a main portion of the IGBT 100 according to the first embodiment. FIG. 2 is a schematic top view of the main portion of the IGBT according to the first embodiment. The cross-sectional view of FIG. 1 is a cross section taken along line A-A in FIG. 2. FIG. 2 is a top view of the IGBT 100 when an emitter electrode is removed.

As shown in FIG. 1 and FIG. 2, the IGBT 100 according to the embodiment includes an n⁻-type base layer 2 (a first semiconductor layer of a first conductivity type), a first trench 3a, a second trench 3b, a first p-type base layer 7a (a first base layer of a second conductivity type), a second p-type base layer 7b (a second base layer of the second conductivity type), a first n⁺-type emitter layer 8a (a first emitter layer of the first conductivity type), a second n⁺-type emitter layer 8b (a second emitter layer of the first conductivity type), a first gate insulating film 4a, a second gate insulating film 4b, a first gate electrode 5a, a second gate electrode 5b, an interlayer insulating film 6, an insulating film 9, a p⁺-type collector layer 1 (a second semiconductor layer of the second conductivity type), a collector electrode 10 (a first electrode), and an emitter electrode 11 (a second electrode).

The n⁻-type base layer 2 has a first surface and a second surface on the opposite side to the first surface. The first trench 3a extends from the first surface of the n⁻-type base layer 2 to the interior of the n⁻-type base layer 2. The first trench 3a extends in a striped configuration along the Y direction (a first direction) in the drawing parallel to the first surface. The second trench 3b extends from the first surface of the n⁻-type base layer 2 to the interior of the n⁻-type base layer 2. The second trench 3b extends in a striped configuration along the Y direction. That is, the second trench 3b is adjacent to the first trench 3a in the X direction (a second direction) in the drawing orthogonal to the Y direction and parallel to the first surface.

The first p-type base layer 7a is selectively formed on the first surface of the n⁻-type base layer 2 between the first trench 3a and the second trench 3b, and is exposed at the side wall of the first trench 3a. The first p-type base layer 7a extends in the Y direction in a striped configuration along the first trench 3a. The second p-type base layer 7b is selectively formed on the first surface of the n⁻-type base layer 2 between the first trench 3a and the second trench 3b, and is exposed at the side wall of the second trench. The second p-type base layer 7b extends in the Y direction in a striped configuration along the second trench 3b. The first p-type base layer 7a is away from the second p-type base layer 7b via the n⁻-type base layer 2 in the X direction.

The first n⁺-type emitter layer 8a is selectively formed on the surface of the first p-type base layer 7a, and is exposed at the side wall of the first trench 3a. The first n⁺-type emitter layer 8a extends in a striped configuration in the Y direction along the first trench 3a. The first n⁺-type emitter layer 8a is composed of a plurality of portions divided along the Y direction, and the plurality of portions are away from one another via the first p-type base layer 7a along the Y direction. The plurality of portions are away from the n⁻-type base layer 2 via the first p-type base layer 7a in the X direction.

The second n⁺-type emitter layer 8b is selectively formed on the surface of the second p-type base layer 7b, and is exposed at the side wall of the second trench 3b. The second n⁺-type emitter layer 8b extends in a striped configuration in the Y direction along the second trench 3b. The second n⁺-type emitter layer 8b is composed of a plurality of portions divided along the Y direction, and the plurality of portions are away from one another via the second p-type base layer 7b along the Y direction. The plurality of portions are away from the n⁻-type base layer 2 via the second p-type base layer 7b in the X direction.

The n⁻-type base layer 2, the first p-type base layer 7a, the second p-type base layer 7b, the first n⁺-type emitter layer 8a, the second n⁺-type emitter layer 8b, and the p⁺-type collector layer 1 described later are semiconductor layers made of silicon.

The first gate electrode 5a is provided on the n⁻-type base layer 2, on the first p-type base layer 7a, and on the first emitter layer 8a via the first gate insulating film 4a in the first trench 3a. The second gate electrode 5b is provided on the n⁻-type base layer 2, on the second p-type base layer 7b, and on the second emitter layer 8b via the second gate insulating film 4b in the second trench 3b. The second gate electrode 5b is electrically connected to the first gate electrode 5a. The first gate electrode and the second gate electrode are drawn out to a not-shown gate electrode pad.

The first gate electrode 5a and the second gate electrode 5b are formed of, for example, conductive polysilicon. The first gate insulating film 4a and the second gate insulating film 4b are formed of, for example, silicon oxide (SiO₂). Instead of silicon oxide, silicon nitride (SiN), silicon oxynitride (SiNO), alumina (Al₂O₃), or the like may be used.

The interlayer insulating film 6 is provided on the first gate electrode 5a and on the second gate electrode 5b. The first gate electrode 5a and the second gate electrode 5b are insulated from the outside by the interlayer insulating film 6 and the first and second gate insulating films 4a and 4b, respectively.

The insulating film 9 is provided on the first p-type base layer 7a and on the second p-type base layer 7b, and covers the first surface of the n⁻-type base layer 2 between the first p-type base layer 7a and the second p-type base layer 7b. The insulating film 9 extends in a striped configuration in the Y direction. The insulating film 9 is separated from the first trench 3a and the second trench 3b in the X direction. The first p-type base layer 7a and the first n⁺-type emitter layer 8a are exposed at the space between the first trench 3a and the insulating film 9. The second p-type base layer 7b and the second n⁺-type emitter layer 8b are exposed at the space between the second trench 3b and the insulating film 9. The interlayer insulating film 6 and the insulating film 9 are formed of silicon oxide, silicon nitride, silicon oxynitride, alumina, or the like similar to the gate insulating film.

The p⁺-type collector layer 1 is provided on the second surface of the n⁻-type base layer 2, and is electrically connected to the n⁻-type base layer 2.

The collector electrode 10 is electrically connected to the p⁺-type collector layer 1. The emitter electrode 11 is electrically connected to the first p-type base layer 7a, the second p-type base layer 7b, the first n⁺-type emitter layer 8a, and the second n⁺-type emitter layer 8b, and is insulated from the first surface of the n⁻-type base layer 2 by the insulating film 9. The emitter electrode and the collector electrode are formed of, for example, copper, aluminum, or the like.

The emitter electrode 11 is directly joined onto the surface of the first p-type base layer 7a and onto the surface of the first n⁺-type emitter layer 8a exposed at the stripe-shaped space between the first trench 3a and the insulating film 9, and is electrically connected to them. The emitter electrode 11 is directly joined onto the surface of the second p-type base layer 7b and onto the surface of the second n⁺-type emitter layer 8b exposed at the stripe-shaped space between the second trench 3b and the insulating film 9, and is electrically connected to them.

The first trench 3a mentioned above and the second trench 3b mentioned above are alternately disposed in a plurality along the X direction. Thereby, a plurality of trenches 3a and 3b are provided on the first surface of the n⁻-type base layer 2. Also between a first trench 3a and a second trench 3b adjacent other than those mentioned above out of the plurality of trenches 3a and 3b, similar to the above, the first p-type base layer 7a, the second p-type base layer 7b, the first n⁺-type emitter layer 8a, the second n⁺-type emitter layer 8b, and the insulating film 9 are provided. Also in a first trench and a second trench adjacent other than those mentioned above, similar to the above, the first gate insulating film 4a, the first gate electrode 5a, the second gate insulating film 4b, the second gate electrode 5b, and the interlayer insulating film 6 are provided. That is, the structure mentioned above between the first trench 3a and the second trench 3b is repeatedly provided in the X direction.

Although the plurality of first n⁺-type emitter layers 8a and the plurality of second n⁺-type emitter layers 8b are arranged in a line in the X direction, it is not necessarily needed to be arranged in a line in the X direction. For example, the plurality of first n⁺-type emitter layers 8a may be arranged slightly out of alignment in the Y direction with respect to the plurality of second n⁺-type emitter layers 8b. That is, the planar pattern on the first surface of the n⁻-type base layer 2 formed of the plurality of first n⁺-type emitter layers 8a and the plurality of second n⁺-type emitter layers 8b may be in a houndstooth check configuration.

Next, before describing operations and effects of the IGBT 100 according to the embodiment, the structure and operations of an IGBT 101 of a comparative example are described.

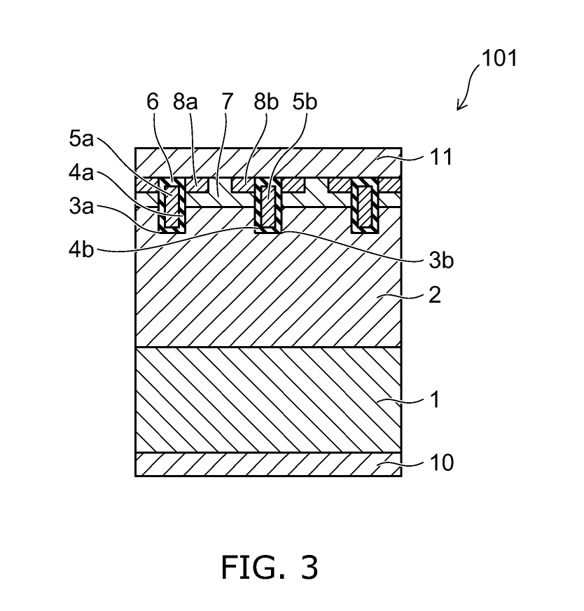

FIG. 3 shows a schematic cross-sectional view of a main portion of the IGBT 101 of the comparative example. The structure of the IGBT 101 of the comparative example includes a p-type base layer 7 provided on the n⁻-type base layer 2 from the first trench 3a to the second trench 3b. That is, the structure is one in which the first p-type base layer 7a and the second p-type base layer 7b are joined into one p-type base layer 7 in the IGBT 100 according to the first embodiment. Furthermore, the IGBT 101 of the comparative example does not include the insulating film 9. The IGBT 101 of the comparative example differs from the IGBT 100 according to the first embodiment in the above respects.

In the IGBT 101 of the comparative example, in a state where a positive voltage with respect to the emitter electrode 11 is applied to the collector electrode 10, when a positive voltage exceeding the threshold is applied to the first gate electrode 5a, a channel layer is formed in a portion of the p-type base layer 7 exposed at the side wall of the first trench 3a. Consequently, electrons flow through the emitter electrode 11, the first n⁺-type emitter layer 8a, the channel layer in the p-type base layer 7, the n⁻-type base layer 2, and the p⁺-type collector layer 1 to the collector electrode 10. Also the second gate electrode undergoes similar operations to the first gate electrode. Corresponding to the flow of electrons, holes flow from the collector electrode 10 through the p⁺-type collector layer 1, the n⁻-type base layer, and the p-type base layer 7 to the emitter electrode 11. At this time, holes injected in the n⁻-type base layer 2 are accumulated in the n⁻-type base layer 2 to cause a conductivity change. Consequently, the n⁻-type base layer 2 becomes low resistive. As holes are more accumulated in the n⁻-type base layer 2, the ON resistance of the IGBT 101 is reduced.

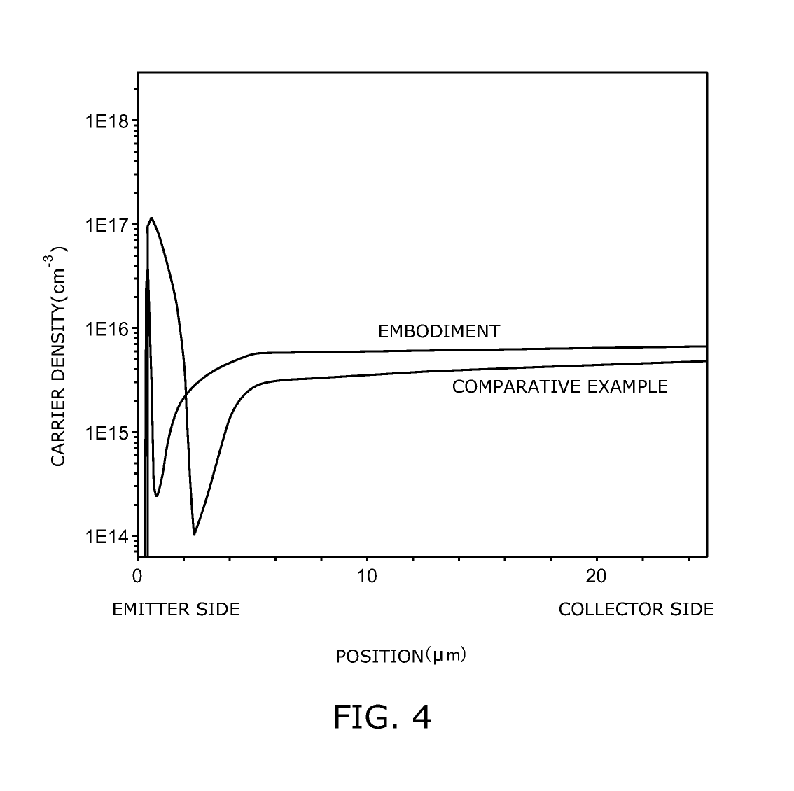

FIG. 4 shows simulation results of the concentration distribution of holes near the emitter electrode in the n⁻-type base layer 2 in the IGBT 100 according to the first embodiment and the IGBT 101 of the comparative example. The simulation was performed with a current density of 200 A/cm².

In the IGBT 101 of the comparative example, since the p-type base layer 7 exists on the emitter electrode 11 side, the concentration of holes is highest in the p-type base layer 7 on the emitter electrode 11 side. Since there is a p-n junction between the p-type base layer 7 and the n⁻-type base layer 2, the concentration of holes greatly decreases here. In the n⁻-type base layer 2, since holes injected from the p⁺-type collector layer 1 are accumulated, the hole concentration is high again. In the n⁻-type base layer 2, the hole concentration gradually increases toward the collector electrode side.

By holes being accumulated in the n⁻-type base layer 2 mentioned above, a conductivity change occurs, and the IGBT 101 has a low ON resistance. To reduce the ON resistance further, a method may be used in which the trench gate space is narrowed to increase the density of the channel layer. However, in the method, the saturation current is increased to reduce the short-circuit withstand capability of the IGBT 101. Furthermore, the gate charge is increased to increase the power loss of a gate drive circuit. Moreover, the gate-emitter capacitance and the gate-collector capacitance are increased to reduce the switching speed of the IGBT. In the structure of the comparative example, a problem like the above occurs when the ON resistance is further reduced.

In contrast, the IGBT 100 according to the embodiment includes the first p-type base layer 7a and the second p-type base layer 7b away from each other via the n⁻-type base layer 2. The first surface of the n⁻-type base layer 2 sandwiched between the first p-type base layer 7a and the second p-type base layer 7b is covered with the insulating film 9. The n⁻-type base layer 2 sandwiched between the first p-type base layer 7a and the second p-type base layer 7b is insulated from the emitter electrode 11 by the insulating film 9. Therefore, holes injected in the n⁻-type base layer 2 from the p⁺-type collector layer 1 flow to the emitter electrode 11 via the first p-type base layer 7a and the second p-type base layer 7b.

In a region distant from a channel region (namely, trench side region of the first p-type base layer 7a and the second p-type base layer 7b) of the IGBT 100 according to the embodiment, compared with the channel region, a p-n junction between the first p-type base layer 7a and the n⁻-type base layer 2 and a p-n junction between the second p-type base layer 7b and the n⁻-type base layer 2 are formed on the emitter electrode side. That is, a depth of the p-n junction mentioned above from the surface of the first p-type base layer 7a or the second p-type base layer 7b decreases as the distance from the channel region increases between the first trench 3a and the second trench 3b. Specifically, in a portion of the n⁻-type base layer 2 sandwiched between the first p-type base layer 7a and the second p-type base layer 2, the portion serving as a current pathway of holes, a position of the p-n junction plane between the first p-type base layer 7a and the n⁻-type base layer 2 and a position of the p-n junction plane between the second p-type base layer 7 and the n⁻-type base layer 2 are located on the emitter electrode side from a position of the p-n junction plane between the p-type base layer 7 and the n⁻-type base layer 2 of the comparative example.

In general, since holes are discharged to the emitter electrode via the p-type base layer by a depletion layer of the p-n junction, hole density is reduced remarkably around the p-n junction. Therefore, similar to the embodiment, it is more difficult for holes to be discharged to the emitter electrode as the p-n junction is located closer to the emitter electrode side (namely, as the p-type base layer is shallower). Here, in the embodiment, since the whole position of the p-n junction plane between the p-type base layer and the n⁻-type base layer is not located on the emitter electrode side uniformly, but the channel region has the configuration similar to the comparative example, the injection amount of electrons can be achieved equal to the comparative example. Therefore, since the channel lengths are equal, the discharged amount of holes can be suppressed without increase of a saturation current or increase of a leak current due to a short channel effect.

Therefore, in the IGBT 100 according to the first embodiment, since holes are more easily accumulated in the n⁻-type base layer 2, the concentration of holes in the n⁻-type base layer 2 is higher than in the IGBT 101 of the comparative example, as shown in FIG. 4. Consequently, in the IGBT 100 according to the first embodiment, the ON resistance is further reduced. That is, in the IGBT 100 according to the embodiment, the ON resistance can be reduced even without narrowing the space between the trench gates to increase the density of the channel layer.

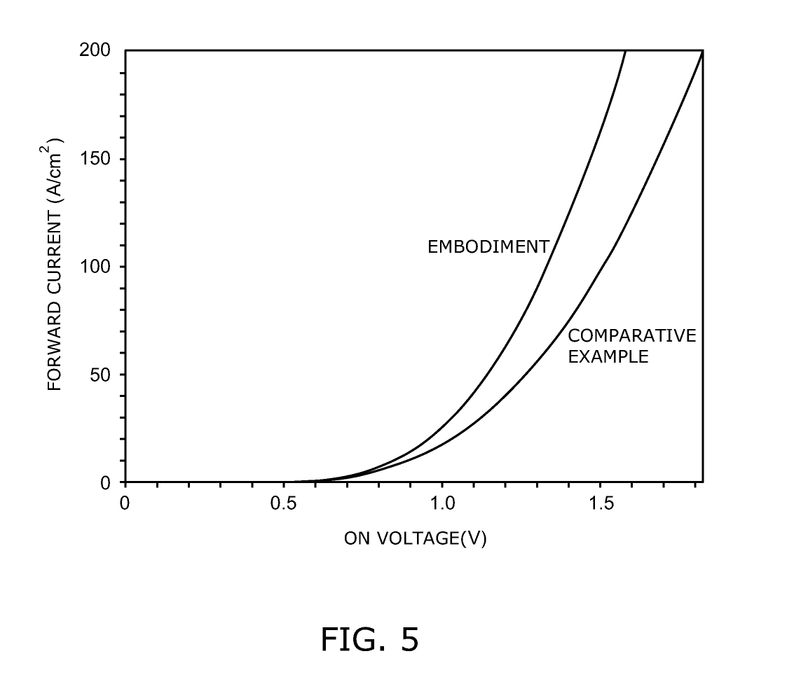

FIG. 5 shows voltage-current characteristics obtained by a simulation of the IGBT 100 according to the first embodiment and the IGBT 101 of the comparative example. At a current density of 200 A/cm², the voltage of the IGBT 100 according to the first embodiment is 1.58 V, and the voltage of the IGBT 101 of the comparative example is 1.82 V. The voltage of the IGBT 100 according to the first embodiment is lower than the voltage of the IGBT 101 of the comparative example. That is, the ON resistance is reduced in the IGBT 100 according to the first embodiment.

As shown above, the IGBT 100 according to the embodiment includes the first p-type base layer 7a and the second p-type base layer 7b away from each other via the n⁻-type base layer 2. The IGBT 100 further includes the insulating film 9 covering the region on the n⁻-type base layer 2 sandwiched between the first p-type base layer 7a and the second p-type base layer 7b. The n⁻-type base layer 2 sandwiched between the first p-type base layer 7a and the second p-type base layer 7b is insulated from the emitter electrode 11 by the insulating film 9. Consequently, in the IGBT 100 according to the embodiment, holes are accumulated in the n⁻-type base layer 2. Therefore, by the embodiment, an IGBT with a low ON resistance can be provided even without narrowing the space between the trench gates to increase the density of the channel layer. As a result, the short-circuit withstand capability of the IGBT can be kept high, and the loss of the gate drive circuit can be reduced.

### Second Embodiment

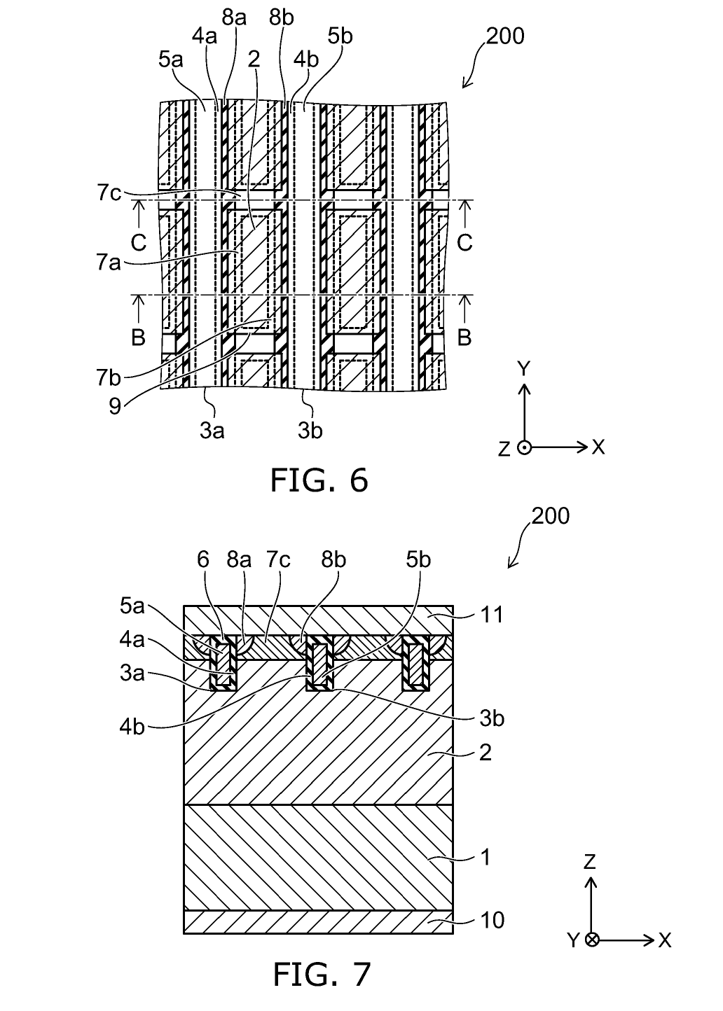

An IGBT 200 according to a second embodiment will now be described using FIG. 6 and FIG. 7. FIG. 6 is a schematic top view of a main portion of the IGBT 200 according to the second embodiment, and is a top view corresponding to FIG. 2 of the IGBT 100 according to the first embodiment. A cross-sectional view taken along line B-B of FIG. 6 is omitted because it is the same as the schematic cross-sectional view of a main portion of the IGBT 100 according to the first embodiment shown in FIG. 1. FIG. 7 shows a schematic cross-sectional view of the main portion taken along line C-C of FIG. 6. Portions having a configuration identical to the configuration described in the first embodiment are marked with the same reference numerals or symbols, and a description thereof is omitted. Differences from the first embodiment are mainly described.

As shown in FIG. 6, in the IGBT 200 according to the embodiment, each of the first n⁺-type emitter layer 8a and the second n⁺-type emitter layer 8b has a striped structure of a single layer extending along the Y direction. As shown in FIG. 7, the IGBT 200 according to the embodiment further includes, on the first surface of the n⁻-type base layer 2, a plurality of third p-type base layers 7c (a plurality of third base layers of the second conductivity type) extending in the X direction and connecting the first p-type base layer 7a and the second p-type base layer 7b. The plurality of third p-type base layers 7c are disposed away from one another via the n⁻-type base layer 2 along the Y direction. The third p-type base layer 7c is a semiconductor layer made of silicon similar to the first and second p-type base layers 7a and 7b.

The insulating film 9 is formed so as to cover a region above the entire first surface of the n⁻-type base layer 2 surrounded by adjacent third p-type base layers 7c out of the plurality of third p-type base layers 7c, the first p-type base layer 7a, and the second p-type base layer 7b. The surrounded first surface of the n⁻-type base layer 2 is insulated from the emitter electrode by the insulating film 9. The insulating film 9 is composed of a plurality of portions divided in the Y direction to be separated from one another. Part of the surface of each of the adjacent third p-type base layers 7c mentioned above is exposed from the insulating film 9. The emitter electrode 11 is electrically connected onto the surfaces of the adjacent third p-type base layers mentioned above exposed from the insulating film 9.

The insulating film 9 is similarly formed also for the other adjacent third p-type base layers 7c. Thus, the emitter electrode 11 is electrically connected onto the surfaces of the third p-type base layers 7c exposed at the spaces between insulating films 9 adjacent in the Y direction.

Each of the first n⁺-type emitter layer 8a and the second n⁺-type emitter layer 8b has a striped structure of a single layer extending along the Y direction. The first n⁺-type emitter layer 8a and the second n⁺-type emitter layer 8b are exposed at the space between the first trench 3a and the insulating film 9 and at the space between the second trench 3b and the insulating film 9, respectively. These spaces extend along the Y direction. The emitter electrode 11 is electrically connected onto the surface of the first n⁺-type emitter layer 8a and onto the surface of the second n⁺-type emitter layer 8b in the portions of these spaces.

The IGBT 200 according to the embodiment differs from the IGBT 100 according to the first embodiment in the above respects.

As illustrated above, the IGBT 200 according to the embodiment includes the first p-type base layer 7a and the second p-type base layer 7b away from each other via the n⁻-type base layer 2 similar to the IGBT 100 according to the first embodiment. The IGBT 200 further includes the insulating film 9 covering the region on the n⁻-type base layer 2 sandwiched between the first p-type base layer 7a and the second p-type base layer 7b. The n⁻-type base layer 2 sandwiched between the first p-type base layer 7a and the second p-type base layer 7b is insulated from the emitter electrode 11 by the insulating film 9.

As a consequence, in the IGBT 200 according to the embodiment, holes are accumulated in the n⁻-type base layer 2. Therefore, by the embodiment, an IGBT with a low ON resistance can be provided even without narrowing the space between the trench gates to increase the density of the channel layer. Consequently, the short-circuit withstand capability of the IGBT can be kept high, and the loss of the gate drive circuit can be reduced.

Furthermore, in the IGBT 200 according to the embodiment, each of the first n⁺-type emitter layer 8a and the second n⁺-type emitter layer 8b has a striped structure of a single layer extending along the Y direction. The first n⁺-type emitter layer 8a and the second n⁺-type emitter layer 8b are electrically connected to the emitter electrode 11 in the space between the first trench 3a and the insulating film 9 extending along the Y direction and in the space between the second trench 3b and the insulating film 9 extending along the Y direction, respectively. Thereby, the contact resistance between the first and second n⁺-type emitter layers and the emitter electrode can be reduced.

Although thereby it becomes difficult for the emitter electrode 11 to obtain a direct electrical connection with the first p-type base layer 7a and the second p-type base layer 7b, the emitter electrode 11 is instead electrically connected to the third p-type base layer 7c in a direct manner. Therefore, the IGBT 200 according to the embodiment can greatly reduce the contact resistance between the emitter electrode 11 and the first and second n⁺-type emitter layers without increasing the contact resistance between the emitter electrode 11 and the first and second p-type base layers 7a and 7b as compared to the IGBT 100 according to the first embodiment.

The insulating film 9 may extend onto the interlayer insulating film 6 provided in the first trench 3a and onto the interlayer insulating film 6 provided in the second trench 3b. Alternatively, the insulating film 9 may extend along the X direction to intersect with the first trench 3a and the second trench 3b. Also in this case, the first n⁺-type emitter layer 8a and the second n⁺-type emitter layer 8b exposed at the spaces between insulating films 9 adjacent in the Y direction are electrically connected to the emitter electrode 11. In this case, the contact resistance between the first n⁺-type emitter layer 8a and the second n⁺-type emitter layer 8b and the emitter electrode 11 is high. However, there is an advantage that processes such as mask alignment in forming the insulating film 9 become easy to increase manufacturing yields.

In the embodiment, the first n⁺-type emitter layer 8a and the second n⁺-type emitter layer 8b are described as a striped structure of a single layer extending along the Y direction. However, similar to the first embodiment, they may be configured by a plurality of portions divided along the Y direction. It is sufficient that at least the first n⁺-type emitter layer 8a and the second n⁺-type emitter layer 8b be electrically connected to the emitter electrode. In this case, although the contact resistance between the first n⁺-type emitter layer 8a and the second n⁺-type emitter layer 8b and the emitter electrode 11 is increased, there is an advantage that the saturation current of the IGBT 200 can be reduced.

Similar to the first embodiment, also a configuration is possible in which the first n⁺-type emitter layer 8a and the second n⁺-type emitter layer 8b are configured by a plurality of portions divided along the Y direction and the emitter electrode 11 is electrically connected to each of the plurality of divided portions. Thereby, there is an advantage that the number of electrical connection points between the first p-type base layer 7a and the emitter electrode 11 and between the second p-type base layer 7b and the emitter electrode 11 is increased and the contact resistance between the first p-type base layer 7a and the emitter electrode 11 and between the second p-type base layer 7b and the emitter electrode 11 is reduced.

### Third Embodiment

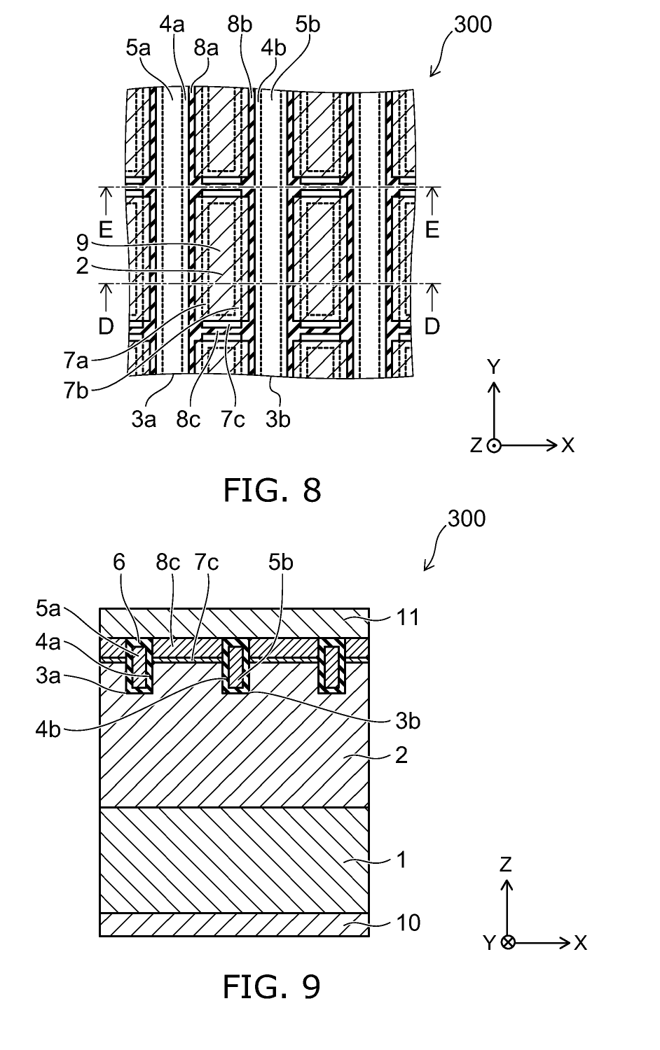

An IGBT 300 according to a third embodiment will now be described using FIG. 8 and FIG. 9. FIG. 8 is a schematic top view of a main portion of the IGBT 300 according to the third embodiment, and is a top view corresponding to FIG. 2 of the IGBT 100 according to the first embodiment. A cross-sectional view taken along line D-D of FIG. 8 is omitted because it is the same as the schematic cross-sectional view of a main portion of the IGBT 100 according to the first embodiment shown in FIG. 1. FIG. 9 is a schematic cross-sectional view of the main portion taken along line E-E of FIG. 8. Portions having a configuration identical to the configuration described in the second embodiment are marked with the same reference numerals or symbols, and a description thereof is omitted. Differences from the second embodiment are mainly described.

In the IGBT 300 according to the embodiment, a third n⁺-type emitter layer 8c is further formed selectively on the surface of the third p-type base layer 7c in the IGBT 200 according to the second embodiment. The third n⁺-type emitter layer 8c electrically connects the first n⁺-type emitter layer 8a and the second n⁺-type emitter layer 8b. The third n⁺-type emitter layer 8c needs only to be formed on the surface of at least one of the plurality of third p-type base layers 7c. Alternatively, the third n⁺-type emitter layer 8c may be selectively formed on the surface of one of adjacent third p-type base layers 7c. Alternatively, the third n⁺-type emitter layer 8c may be formed in each of the plurality of third p-type base layers 7c. The third n⁺-type emitter layer 8c is a semiconductor layer made of silicon similar to the first and second n⁺-type emitter layers 8a and 8b.

The emitter electrode 11 is electrically connected onto the surface of the third n⁺-type emitter layer 8c and onto the surface of the third p-type base layer 7c on which the third n⁺-type emitter layer 8c is formed.

The IGBT 300 according to the embodiment differs from the IGBT 200 according to the second embodiment in the above respects.

The IGBT 300 according to the embodiment has similar effects to the IGBT 200 according to the second embodiment. In the IGBT 300 according to the embodiment, since the third n⁺-type emitter layer 8c is further included as compared to the IGBT 200 according to the second embodiment, the contact resistance between the first and second n⁺-type emitter layers 8a and 8b and the emitter electrode 11 is further reduced.

Similar to the second embodiment, the insulating film 9 may extend onto the interlayer insulating film 6 provided in the first trench 3a and onto the interlayer insulating film 6 provided in the second trench 3b. Alternatively, the insulating film 9 may extend along the X direction to intersect with the first trench 3a and the second trench 3b. In this case, similar to the second embodiment, the contact resistance between the first n⁺-type emitter layer 8a and the emitter electrode 11 and between the second n⁺-type emitter layer 8b and the emitter electrode 11 is increased. However, there is an advantage that processes such as mask alignment in forming the insulating film become easy to increase manufacturing yields. The configuration of the insulating film 9 mentioned above can be used in combination with other modification examples described below of the embodiment as a matter of course.

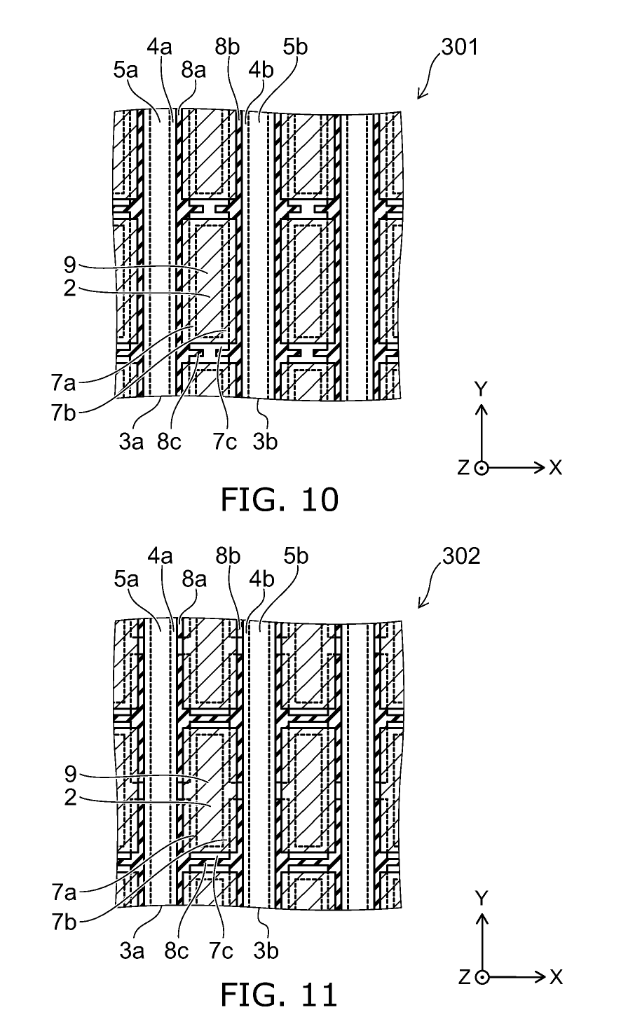

As shown in FIG. 10 that is a schematic top view of a main portion of an IGBT 301 of a modification example of the embodiment, the third n⁺-type emitter layer 8c may be divided into two portions with a space therebetween. In this case, although the contact resistance between the third n⁺-type emitter layer 8c and the emitter electrode 11 is increased, in accordance with this there is an effect in which the contact resistance between the third p-type base layer 7c and the emitter electrode 11 is reduced.

In the embodiment, the first n⁺-type emitter layer 8a and the second n⁺-type emitter layer 8b are described as a striped structure of a single layer extending along the Y direction. However, similar to the first embodiment, as shown in FIG. 11 that is a schematic top view of a main portion of an IGBT 302 of another modification example of the embodiment, each of the first n⁺-type emitter layer 8a and the second n⁺-type emitter layer 8b may be configured by a plurality of portions divided along the Y direction. It is sufficient that at least the first n⁺-type emitter layer 8a and the second n⁺-type emitter layer 8b be electrically connected to the emitter electrode. Further, it is sufficient that at least the first n⁺-type emitter layer 8a and the second n⁺-type emitter layer 8b be electrically connected to the third n⁺-type emitter layer 8c.

In the case of the modification example of FIG. 11, each of the first n⁺-type emitter layer 8a and the second n⁺-type emitter layer 8b has a space between third n⁺-type emitter layers 8c adjacent in the Y direction and is divided into a plurality of portions in the Y direction by the space. In this case, although the contact resistance between the first n⁺-type emitter layer 8a and the emitter electrode 11 and between the second n⁺-type emitter layer 8b and the emitter electrode 11 is increased, there is an advantage that the saturation current of the IGBT 300 can be reduced.

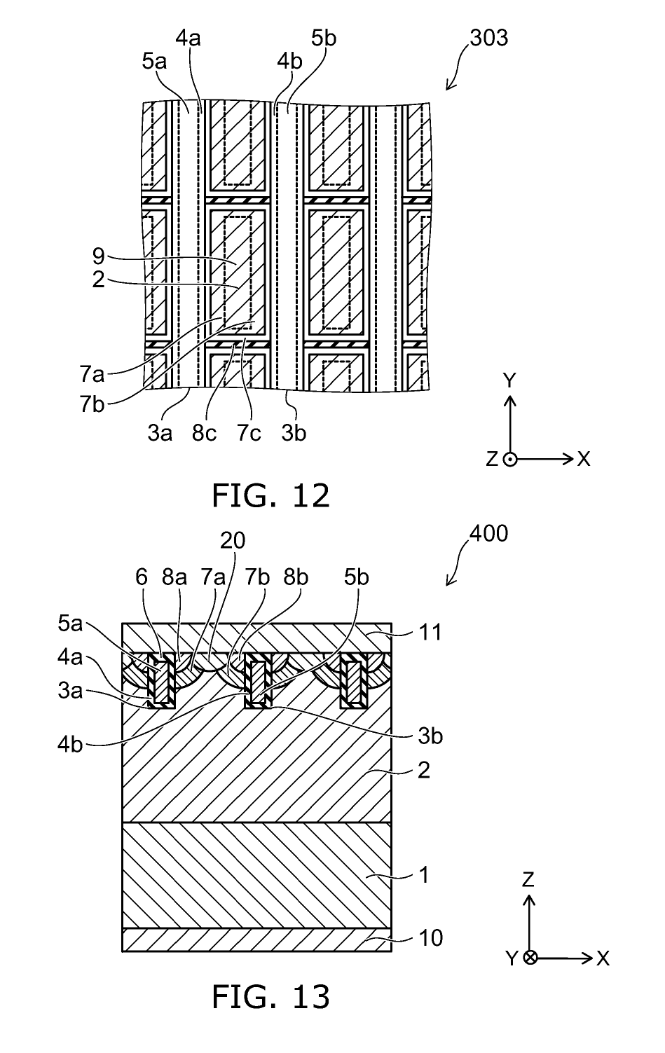

In addition, FIG. 12 shows a schematic top view of a main portion of an IGBT 303 of another modification example of the embodiment. In the IGBT 303, the first n⁺-type emitter layer 8a and the second n⁺-type emitter layer 8b do not exist. Instead, the third n⁺-type emitter layer 8c is exposed at the side wall of the first trench 3a and the side wall of the second trench 3b, and is electrically connected to channel layers formed in the first and second p-type base layers 7a and 7b. The IGBT 303 of this modification example corresponds to the case where, in the IGBT 302 of the modification example shown in FIG. 11, the width of the space dividing the first n⁺-type emitter layer 8a and the second n⁺-type emitter layer 8b into a plurality of portions in the Y direction is most widened. In the IGBT 303, although the contact resistance between the n⁺-type emitter layer 8 and the emitter electrode 11 is still higher than in the IGBT 302, the saturation current can be further reduced.

In the IGBT 300 according to the embodiment, similar to the first embodiment, also a configuration is possible in which the first n⁺-type emitter layer 8a and the second n⁺-type emitter layer 8b are configured by a plurality of portions divided along the Y direction and the emitter electrode 11 is electrically connected to each of the plurality of divided portions. Thereby, there is an advantage that the number of electrical connection points between the first p-type base layer 7a and the emitter electrode 11 and between the second p-type base layer 7b and the emitter electrode 11 is increased and the contact resistance between the first p-type base layer 7a and the emitter electrode 11 and between the second p-type base layer 7b and the emitter electrode 11 is reduced.

### Fourth Embodiment

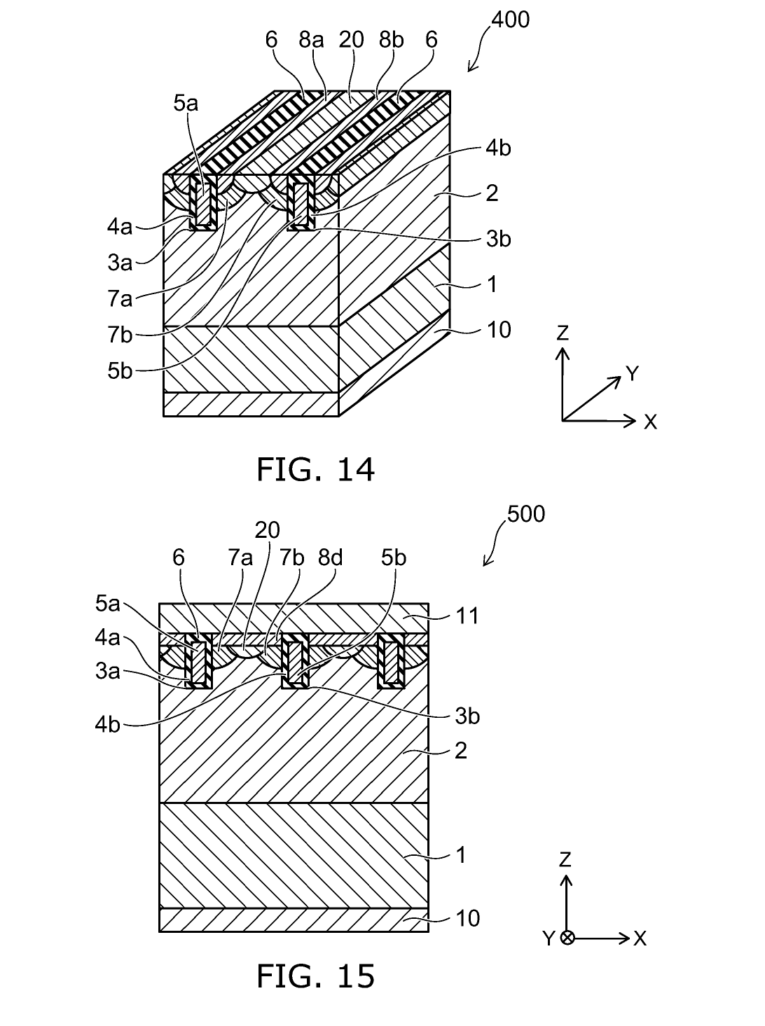

An IGBT 400 according to a fourth embodiment will now be described using FIG. 13 and FIG. 14. FIG. 13 is a schematic cross-sectional view of a main portion of the IGBT 400 according to the fourth embodiment, and is a cross-sectional view corresponding to FIG. 1 of the IGBT 100 according to the first embodiment. FIG. 14 is a schematic perspective view of a main portion of the IGBT 400 according to the embodiment. In FIG. 14, the source electrode 11 is omitted. Portions having a configuration identical to the configuration described in the first embodiment are marked with the same reference numerals or symbols, and a description thereof is omitted. Differences from the first embodiment are mainly described.

As shown in FIG. 13 and FIG. 14, the IGBT 400 according to the embodiment does not include the insulating layer 9 covering the n⁻-type base layer 2 sandwiched between the first p-type base layer 7a and the second p-type base layer 7b. Instead of it, the IGBT 400 according to the embodiment includes a p⁺-type contact layer 20 provided on a surface of the portion of the n⁻-type base layer 2 sandwiched between the first p-type base layer 7a and the second p-type base layer 7b.

The p⁺-type contact layer 20 extends along the Y direction in a striped configuration. The p⁺-type contact layer 20 is electrically connected to the first p-type base layer 7a and the second p-type base layer 7b in the X direction. A bottom of the p⁺-type contact layer 20 is located on the emitter electrode side from a bottom of the first p-type base layer 7a and a bottom of the second p-type base layer 7b. That is, the p⁺-type contact layer 20 is formed from the emitter electrode side shallower than the first p-type base layer 7a and the second p-type base layer 7b. The p⁺-type contact layer 20, for example, a semiconductor made of silicon, its p-type impurity concentration may be the same as the impurity concentration of the first p-type base layer 7a and the second p-type base layer 7b, but favorably higher.

In the IGBT 400 according to the embodiment, each of the first n⁺-type emitter layer 8a and the second n⁺-type emitter layer 8b extends along the first trench 3a and the second trench 3b in the Y direction in a striped configuration in a monolayer.

The IGBT 400 according to the embodiment differes from the IGBT 100 according to the first embodiment in the above respects.

Similar to the IGBT according to the first embodiment, the IGBT 400 according to the embodiment includes the first p-type base layer 7a and the second p-type base layer 7b separated each other via the n⁻-type base layer 2. Consequently, also in the IGBT 400 according to the embodiment, the p-n junction between the p-type base layer 7 and the n⁻-type base layer 2 is close to the emitter electrode side in the n⁻-type base layer 2 sandwiched between the first p-type base layer 7a and the second p-type base layer 7b, and thus holes are accumulated in the n⁻-type base layer 2. Therefore, the embodiment also can provide an IGBT having a low ON resistance, even if the density of the channel is not increased by making the spaces between the trenches narrow. As a result, the short circuit withstand capability of the IGBT can be maintained high and the loss of the gate drive circuit can be small.

The IGBT 400 according to the embodiment includes the p⁺-type contact layer 20 provided on the n⁻-type base layer 2 sandwiched between the first p-type base layer 7a and the second p-type base layer 7b. The n⁻-type base layer 2 is electrically connected to the emitter electrode 11 via the p⁺-type contact layer 20. Consequently, in the IGBT 400 according to the embodiment compared with the IGBT 100 according to the first embodiment, holes are easy to be discharged to the emitter electrode via the p⁺-type contact layer 20. Therefore, the IGBT 400 according to the embodiment has an advantage such that switching from the ON state to the OFF state is fast and responsiveness is high. Furthermore, there exists an advantage such that avalanche withstand capability is improved because a number of holes generated by avalanche breakdown at turn off switching are discharged immediately to the emitter electrode. That is, there exists an advantage of operating with more safety against the breakdown at the turn off switching. In the IGBT 400 according to the embodiment, holes can be easy to be accumulated and discharged.

### Fifth Embodiment

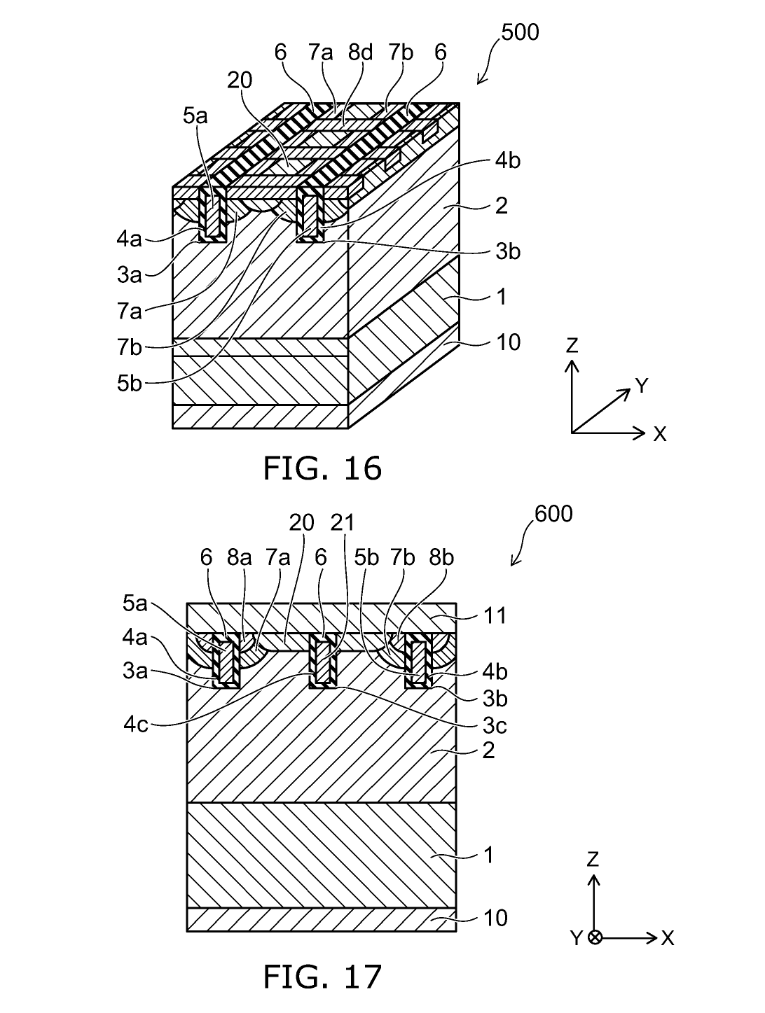

An IGBT 500 according to a fifth embodiment will now be described using FIG. 15 and FIG. 16. FIG. 15 is a schematic cross-sectional view of a main portion of the IGBT 500 according to the fifth embodiment, and is a cross-sectional view corresponding to FIG. 1 of the IGBT 100 according to the first embodiment. FIG. 16 is a schematic perspective view of a main portion of the IGBT 500 according to the embodiment. In FIG. 16, the source electrode 11 is omitted. Portions having a configuration identical to the configuration described in the fourth embodiment are marked with the same reference numerals or symbols, and a description thereof is omitted. Differences from the fourth embodiment are mainly described.

As shown in FIG. 15 and FIG. 16, in the IGBT 500 according to the embodiment, the first n⁺-type emitter layer 8a and the second n⁺-type emitter layer 8b extend in the X direction and combine with each other to constitute a fourth n⁺-type emitter layer 8d. A plurality of fourth n⁺-type emitter layers 8d are arranged separated from each other along the Y direction. The IGBT 500 according to the embodiment differes from the IGBT 400 according to the fourth embodiment in this respect.

As described above, in the IGBT 500 according to the embodiment, since the plurality of fourth n⁺-type emitter layers 8d are provided so as to reach the side wall of the second trench 3b from the side wall of the first trench 3a, bad influence to the operation characteristics due to mask misalignment does not almost occur. Except this point, also in the IGBT 500 according to the embodiment, the effect similar to the effect obtained in the IGBT 400 according to the fourth embodiment is obtained.

### Sixth Embodiment

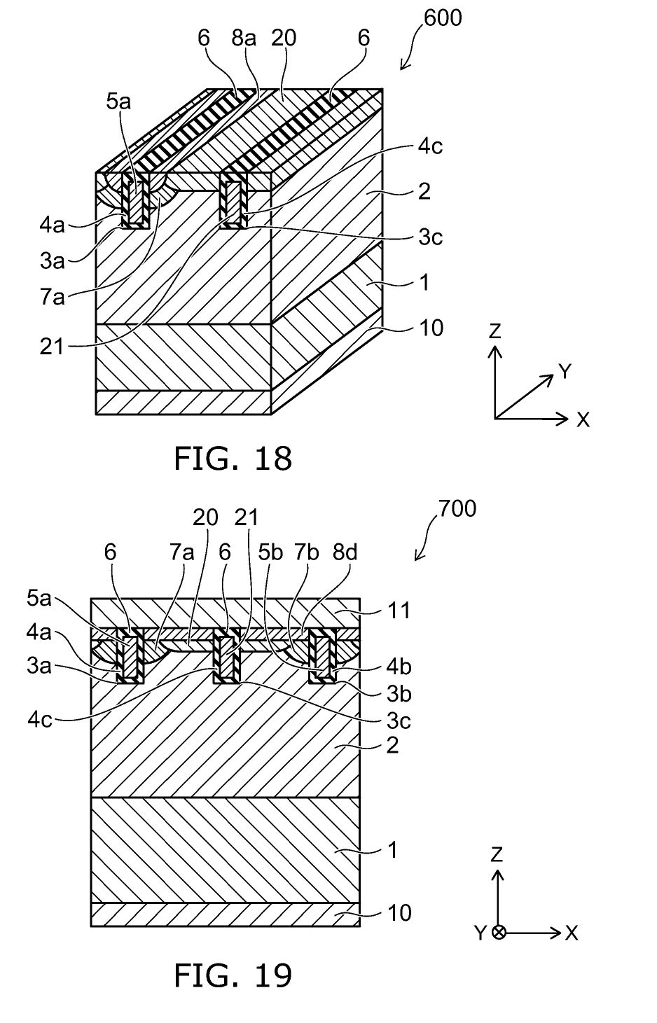

An IGBT 600 according to a sixth embodiment will now be described using FIG. 17 and FIG. 18. FIG. 17 is a schematic cross-sectional view of a main portion of the IGBT 600 according to the sixth embodiment, and is a cross-sectional view corresponding to FIG. 1 of the IGBT 100 according to the first embodiment. FIG. 18 is a schematic perspective view of a main portion of the IGBT 600 according to the embodiment. In FIG. 18, the source electrode 11 is omitted. Portions having a configuration identical to the configuration described in the fourth embodiment are marked with the same reference numerals or symbols, and a description thereof is omitted. Differences from the fourth embodiment are mainly described.

As shown in FIG. 17 and FIG. 18, the IGBT 600 according to the embodiment includes a third trench 3c. The third trench 3c goes through the p⁺-type contact layer 20 from the surface of the p⁺-type contact layer 20, extends into the portion of the n⁻-type base layer 2 sandwiched between the first p-type base layer 7a and the second p-type base layer 7b, and extends in the p⁺-type contact layer 20 and the n⁻-type base layer 2 along the Y direction. A conductor 21 formed of conductive material is provided on the p⁺-type contact layer 20 and the n⁻-type base layer 2 in the third trench 3c via an insulating film 4c.

For example, the insulating film 4c may be formed integrally with the first insulating film 4a and the second insulating film 4b, but is not limited thereto. The insulating film 4c is possible to be thicker than the first insulating film 4a and the second insulating film 4b as well. The conductor 21 may be formed integrally with the first gate electrode 5a and the second gate electrode 5b, but is not limited thereto. The interlayer insulating film 6 is provided so as to cover the conductor 21, but is not always needed. The conductor 21 is electrically connected to the emitter electrode 11 via the opening of the interlayer insulating film 6 in a portion not shown.

The IGBT 600 according to the embodiment differs from the IGBT 400 according to the fourth embodiment in the above respects. In order to describe the effect of the IGBT 600 according to the embodiment, the conductor 21 and the insulating film 4c are provided between the first gate electrode 5a and the second gate electrode 5b so that the space between the first gate electrode 5a and the conductor 21 of the IGBT 600 according to the embodiment is, as one example, equal to the space between the first gate electrode 5a and the second gate electrode 5b of the IGBT 400 according to the fourth embodiment.

In the IGBT 600 according to the embodiment, since the conductor 21 has an emitter potential, holes injected into the n⁻-type base layer 2 from the p⁺-type collector layer 1 are drawn to the conductor 21 side to flow into the emitter electrode 11 through the p⁺-type contact layer 20 from the n⁻-type base layer 2. Since a bottom (p-n junction) of the p⁺-type contact layer 20 is located on the emitter electrode side from a bottom (p-n junction) of the first p-type base layer 7a, holes are difficult to be discharged from the n⁻-type base layer 2 compared with the IGBT 400 according to the fourth embodiment. As a result, in the IGBT 600 according to the embodiment, holes are further accumulated in the n⁻-type base layer 2 compared with the IGBT 400 according to the fourth embodiment. Consequently, the ON resistance is further reduced.

In respects other than the above, in the IGBT 600 according to the embodiment, the space between the first gate electrode 5a and the second gate electrode 5b is twice as the space in the IGBT 400 according to the fourth embodiment. This reduces the density in the channel layer to a half in the IGBT 600 according to the embodiment compared with the IGBT 400 according to the fourth embodiment. As a result, in the IGBT 600 according to the embodiment, the saturation current is possible to be further reduced and significant improvement of the short circuit withstand capability is possible compared with the IGBT 400 according to the fourth embodiment.

Correspondingly, in the IGBT 600 according to the embodiment compared with the IGBT 400 according to the fourth embodiment, since the area of the gate electrode opposing the emitter electrode 11 and the area of the gate electrode opposing the collector electrode 10 are reduced to a half, capacitance between gate-emitter and capacitance between gate-collector are greatly reduced as well. As a result, the IGBT 600 according to the embodiment makes it possible to reduce the power loss of the gate drive circuit and makes it possible to downsize the gate drive circuit and to operate it with a high speed compared with the IGBT 400 according to the fourth embodiment. The switching speed of the IGBT 600 according to the embodiment is improved as well.

Except respects described above, also in the IGBT 600 according to the embodiment, the effect similar to the effect obtained in the IGBT 400 according to the fourth embodiment is obtained.

### Seventh Embodiment

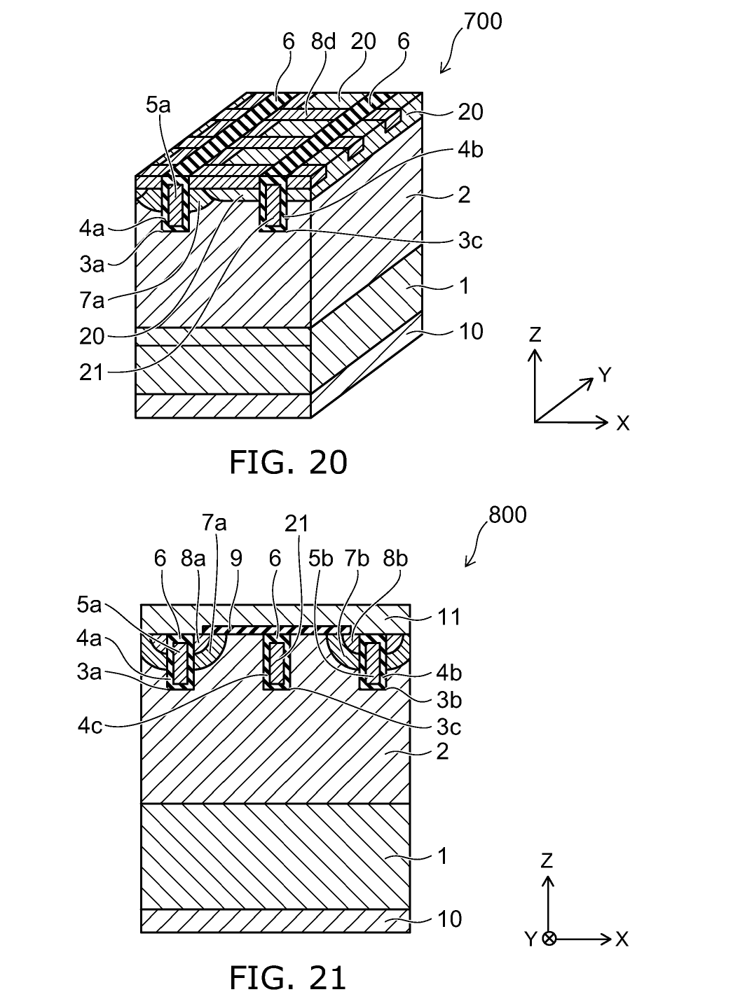

An IGBT 700 according to a seventh embodiment will now be described using FIG. 19 and FIG. 20. FIG. 19 is a schematic cross-sectional view of a main portion of the IGBT 700 according to the seventh embodiment, and is a cross-sectional view corresponding to FIG. 1 of the IGBT 100 according to the first embodiment. FIG. 20 is a schematic perspective view of a main portion of the IGBT 700 according to the embodiment. In FIG. 20, the source electrode 11 is omitted. Portions having a configuration identical to the configuration described in the fifth embodiment are marked with the same reference numerals or symbols, and a description thereof is omitted. Differences from the fifth embodiment are mainly described.

As shown in FIG. 19 and FIG. 20, the IGBT 700 according to the embodiment includes the third trench 3c. The third trench 3c goes through the p⁺-type contact layer 20 and the fourth n⁺-type emitter layer 8d from the surface of the p⁺-type contact layer 20 and the fourth n⁺-type emitter layer 8d, extends into the portion of the n⁻-type base layer 2 sandwiched between the first p-type base layer 7a and the second p-type base layer 7b, and extends in the p⁺-type contact layer 20 and the n⁻-type base layer 2 along the Y direction. The plurality of the fourth n⁺-type emitter layers 8d are divided by the third trench. The conductor 21 formed of conductive material is provided on the fourth n⁺-type emitter layer 8d, the p⁺-type contact layer 20, and the n⁻-type base layer 2 in the third trench 3c via the insulating film 4c.

For example, the insulating film 4c may be formed integrally with the first insulating film 4a and the second insulating film 4b, but is not limited thereto. The insulating film 4c is possible to be thicker than the first insulating film 4a and the second insulating film 4b as well. The conductor 21 may be formed integrally with the first gate electrode 5a and the second gate electrode 5b, but is not limited thereto. The interlayer insulating film 6 is provided so as to cover the conductor 21, but is not always needed. The conductor 21 is electrically connected to the emitter electrode 11 via the opening of the interlayer insulating film 6 in a portion not shown.

The IGBT 700 according to the embodiment differs from the IGBT 500 according to the fifth embodiment in the above respects. In order to describe the effect of the IGBT 700 according to the embodiment, the conductor 21 and the insulating film 4c are provided between the first gate electrode 5a and the second gate electrode 5b so that the space between the first gate electrode 5a and the conductor 21 of the IGBT 700 according to the embodiment is, as one example, equal to the space between the first gate electrode 5a and the second gate electrode 5b of the IGBT 500 according to the fifth embodiment.

In the IGBT 700 according to the embodiment, since the conductor 21 has an emitter potential, holes injected into the n⁻-type base layer 2 from the p⁺-type collector layer 1 are drawn to the conductor 21 side to flow into the emitter electrode 11 through the p⁺-type contact layer 20 from the n⁻-type base layer 2. Since a bottom (p-n junction) of the p⁺-type contact layer 20 is located on the emitter electrode side from a bottom (p-n junction) of the first p-type base layer 7a, holes are difficult to be discharged from the n⁻-type base layer 2 compared with the IGBT 500 according to the fifth embodiment. As a result, in the IGBT 700 according to the embodiment, holes are further accumulated in the n⁻-type base layer 2 compared with the IGBT 500 according to the fifth embodiment. Consequently, the ON resistance is further reduced.

In respects other than the above, in the IGBT 700 according to the embodiment, the space between the first gate electrode 5a and the second gate electrode 5b is twice as the space in the IGBT 500 according to the fifth embodiment. This reduces the density in the channel layer to a half in the IGBT 700 according to the embodiment compared with the IGBT 500 according to the fifth embodiment. As a result, in the IGBT 700 according to the embodiment, the saturation current is possible to be further reduced and significant improvement of the short circuit withstand capability is possible compared with the IGBT 500 according to the fifth embodiment.

Correspondingly, in the IGBT 700 according to the embodiment compared with the IGBT 500 according to the fifth embodiment, since the area of the gate electrode opposing the emitter electrode 11 and the area of the gate electrode opposing the collector electrode 10 are reduced to a half, capacitance between gate-emitter and capacitance between gate-collector are greatly reduced as well. As a result, the IGBT 700 according to the embodiment makes it possible to reduce the power loss of the gate drive circuit and makes it possible to downsize the gate drive circuit and to operate it with a high speed compared with the IGBT 500 according to the fifth embodiment. The switching speed of the IGBT 700 according to the embodiment is improved as well.

Except respects described above, also in the IGBT 700 according to the embodiment, the effect similar to the effect obtained in the IGBT 500 according to the fifth embodiment is obtained.

### Eighth Embodiment

An IGBT 800 according to an eighth embodiment will now be described using FIG. 21. FIG. 21 is a schematic cross-sectional view of a main portion of the IGBT 800 according to the eighth embodiment, and is a cross-sectional view corresponding to FIG. 1 of the IGBT 100 according to the first embodiment. Portions having a configuration identical to the configuration described in the first embodiment are marked with the same reference numerals or symbols, and a description thereof is omitted. Differences from the first embodiment are mainly described.

As shown in FIG. 21, the IGBT 800 according to the embodiment includes the third trench 3c. The third trench 3c extends in the n⁻-type base layer 2 from the surface of the portion of the n⁻-type base layer 2 sandwiched between the first p-type base layer 7a and the second p-type base layer 7b toward the collector electrode 10, and extends in the n⁻-type base layer 2 along the Y direction. The conductor 21 formed of conductive material is provided on the n⁻-type base layer 2 in the third trench 3c via the insulating film 4c. The insulating film 4c and the conductor 21 are formed similar to the sixth embodiment and the seventh embodiment. The interlayer insulating film 6 is provided so as to cover the conductor 21, however it is sufficient for the insulating film 9 to cover the conductor 21 directly even if the interlayer insulating film 6 does not cover the conductor 21.

The IGBT 800 according to the embodiment differs from the IGBT 100 according to the first embodiment in the above respects. In order to describe the effect of the IGBT 800 according to the embodiment, the conductor 21 and the insulating film 4c are provided between the first gate electrode 5a and the second gate electrode 5b so that the space between the first gate electrode 5a and the conductor 21 of the IGBT 800 according to the embodiment is, as one example, equal to the space between the first gate electrode 5a and the second gate electrode 5b of the IGBT 100 according to the first embodiment.

In the IGBT 800 according to the embodiment, since the conductor 21 has an emitter potential, holes injected into the n⁻-type base layer 2 from the p⁺-type collector layer 1 are drawn to the conductor 21 side. Consequently, holes are made difficult to be discharged from the n⁻-type base layer 2 to the emitter electrode 11 via the first p-type base layer 7a. As a result, in the IGBT 800 according to the embodiment, holes result in further being accumulated in the n⁻-type base layer 2 compared with the IGBT 100 according to the first embodiment. Consequently, the ON resistance of the IGBT 800 according to the embodiment is further reduced.

In respects other than the above, in the IGBT 800 according to the embodiment, the space between the first gate electrode 5a and the second gate electrode 5b is twice as the space in the IGBT 100 according to the first embodiment. This reduces the density in the channel layer to a half in the IGBT 800 according to the embodiment compared with the IGBT 100 according to the first embodiment. As a result, in the IGBT 800 according to the embodiment, the saturation current is possible to be further reduced and significant improvement of the short circuit withstand capability is possible compared with the IGBT 100 according to the first embodiment.

Correspondingly, in the IGBT 800 according to the embodiment compared with the IGBT 100 according to the first embodiment, since the area of the gate electrode opposing the emitter electrode 11 and the area of the gate electrode opposing the collector electrode 10 are reduced to a half, capacitance between gate-emitter and capacitance between gate-collector are greatly reduced as well. As a result, the IGBT 800 according to the embodiment makes it possible to reduce the power loss of the gate drive circuit and makes it possible to downsize the gate drive circuit and to operate it with a high speed compared with the IGBT 100 according to the first embodiment. The switching speed of the IGBT 800 according to the embodiment is improved as well.

### Ninth Embodiment

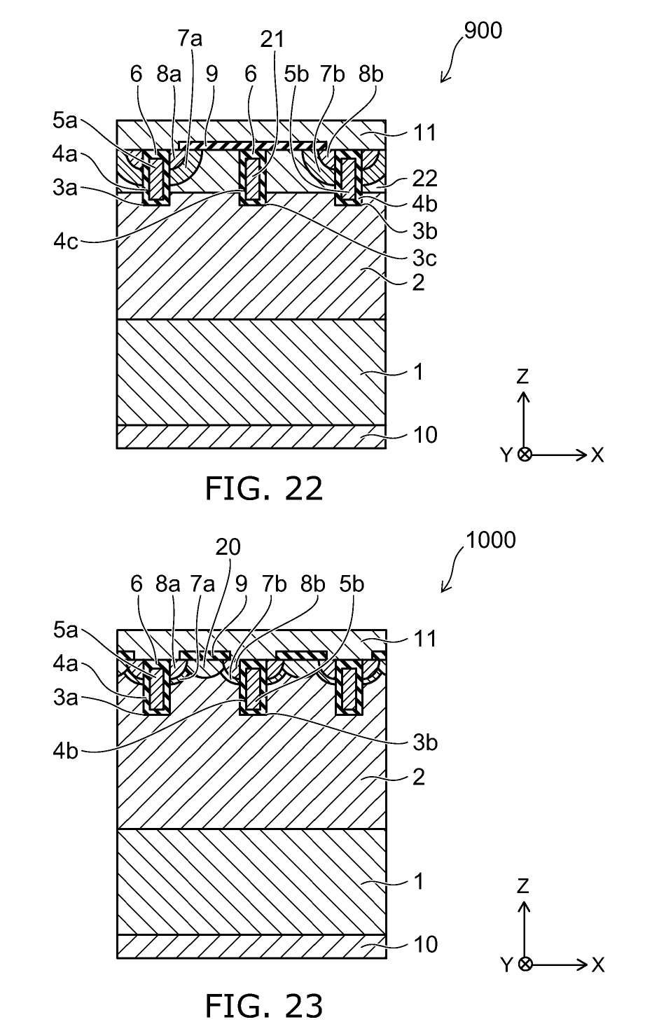

An IGBT 900 according to a ninth embodiment will now be described using FIG. 22. FIG. 22 is a schematic cross-sectional view of a main portion of the IGBT 900 according to the ninth embodiment. Portions having a configuration identical to the configuration described in the eighth embodiment are marked with the same reference numerals or symbols, and a description thereof is omitted. Differences from the eighth embodiment are mainly described.

As shown in FIG. 22, the IGBT 900 according to the embodiment further includes an n-type barrier layer 22 compared with the IGBT 800 according to the eighth embodiment. The n-type barrier layer 22 is, for example, a semiconductor layer made of silicon. In other words, the n⁻-type base layer 2 includes the n-type barrier layer 22 in a portion of the n⁻-type base layer 2 sandwiched between the first p-type base layer 7a and the second p-type base layer 7b. The n-type barrier layer 22 has a concentration of an impurity of the first conductivity type higher than a concentration of the n-type impurity of the n⁻-type base layer 2. The upper layer of the n-type barrier layer 22 is covered with the insulating film 9. The upper layer of the n-type barrier layer 22 is insulated from the emitter electrode 11 by the insulating film 9. The conductor 21 provided inside the third trench 3c via the insulating film 4c goes through the n-type barrier layer 22 from the upper surface of the n-type barrier layer 22.

The IGBT 900 according to the embodiment differs from the IGBT 800 according to the eighth embodiment in the above respects. The n-type barrier layer 22 exists between the first p-type base layer 7a and the n⁻-type base layer 2 and between the second p-type base layer 7 and the n⁻-type base layer 2. Consequently, an energy level of an upper end of a valence band of the n-type barrier layer 22 is lower than an energy level of an upper end of a valence band of the n⁻-type base layer 2. As a result, since the n-type barrier layer 22 operates as a potential barrier to holes in the n⁻-type base layer 2, holes are made difficult to be discharged from the n⁻-type base layer 2 to the first p-type base layer 7a and the second p-type base layer 7b. Therefore, in the IGBT 900 according to the embodiment, since holes are further accumulated in the n⁻-type base layer 2 compared with the IGBT 800 according to the eighth embodiment, the ON resistance of the IGBT 900 according to the embodiment is further reduced.

### Tenth Embodiment

An IGBT 1000 according to a tenth embodiment will now be described using FIG. 23. FIG. 23 is a schematic cross-sectional view of a main portion of the IGBT 1000 according to the tenth embodiment. Portions having a configuration identical to the configuration described in the first embodiment are marked with the same reference numerals or symbols, and a description thereof is omitted. Differences from the first embodiment are mainly described.

As shown in FIG. 23, the IGBT 1000 according to the embodiment includes the p⁺-type contact layer 20 provided on a surface of the portion of the n⁻-type base layer 2 sandwiched between the first p-type base layer 7a and the second p-type base layer 7b. The IGBT 1000 according to the embodiment differs from the IGBT 100 according to the first embodiment in this respect. The IGBT 1000 according to the embodiment differs from the IGBT 400 according to the fourth embodiment in the aspect of the insulating film 9 provided between the p⁺-type contact layer 20 and the emitter electrode 11.

Since the IGBT 1000 according to the embodiment includes the first p-type base layer 7a and the second p-type base layer 7b separated from each other via the n⁻-type base layer 2 similar to the IGBT 100 according to the first embodiment. Therefore in the IGBT 1000 according to the embodiment, the p-n junction between the p-type base layer and the n⁻-type base layer 2 is close to the emitter electrode side in the portion of the n⁻-type base layer 2 sandwiched between the first p-type base layer 7a and the second p-type base layer 7b, and thus holes are accumulated in the n⁻-type base layer 2. As a result, the ON resistance of the IGBT 1000 according to the embodiment is low.

Furthermore, since the IGBT 1000 according to the embodiment includes the p⁺-type contact layer 20, holes are made easy to be discharged to the emitter electrode side compared with the IGBT 100 according to the first embodiment. Therefore, in the IGBT 1000 according to the embodiment, switching from the ON state to the OFF state is fast and responsiveness is high. Furthermore, there exists an advantage such that avalanche withstand capability is improved because a number of holes generated by avalanche breakdown at turn off switching are discharged immediately to the emitter electrode. That is, there exists an advantage of operating with more safety against the breakdown at the turn off switching.

### Eleventh Embodiment

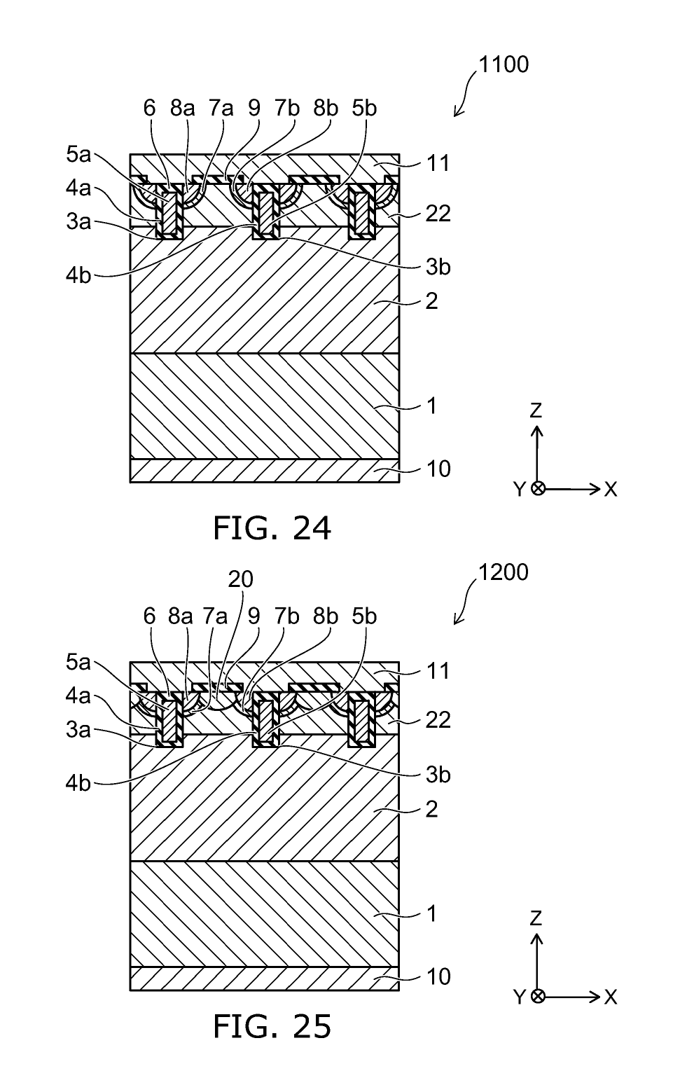

An IGBT 1100 according to an eleventh embodiment will now be described using FIG. 24. FIG. 24 is a schematic cross-sectional view of a main portion of the IGBT 1100 according to the eleventh embodiment. Portions having a configuration identical to the configuration described in the first embodiment are marked with the same reference numerals or symbols, and a description thereof is omitted. Differences from the first embodiment are mainly described.

As shown in FIG. 24, in the IGBT 1100 according to the embodiment, similar to the IGBT 900 according to the ninth embodiment, the n⁻-type base layer 2 includes the n-type barrier layer 22 in a portion of the n⁻-type base layer 2 sandwiched between the first p-type base layer 7a and the second p-type base layer 7b. The IGBT 1100 according to the embodiment differs from the IGBT 100 according to the first embodiment in this respect.

In IGBT 1100 according to the embodiment, the n-type barrier layer 22 operates as a potential barrier to holes in the n⁻-type base layer 2 as described in the ninth embodiment. Consequently, holes are made difficult to be discharged from the n⁻-type base layer 2 to the first p-type base layer 7a and the second p-type base layer 7b. As a result, in the IGBT 1100 according to the embodiment, holes are further accumulated in the n⁻-type base layer 2 compared with the IGBT 100 according to the first embodiment. Consequently, the ON resistance is further reduced.

### Twelfth Embodiment

An IGBT 1200 according to a twelfth embodiment will now be described using FIG. 25. FIG. 25 is a schematic cross-sectional view of a main portion of the IGBT 1200 according to the twelfth embodiment. Portions having a configuration identical to the configuration described in the tenth embodiment are marked with the same reference numerals or symbols, and a description thereof is omitted. Differences from the tenth embodiment are mainly described.

As shown in FIG. 25, the IGBT 1200 according to the embodiment includes the n-type barrier layer 22 in the portion sandwiched between the first p-type base layer 7a and the second p-type base layer 7b similar to the IGBT 1100 according to the eleventh embodiment. The IGBT 1200 according to the embodiment differs from the IGBT 1000 according to the tenth embodiment in this respect. In other words, the IGBT 1200 according to the embodiment has a structure combining the structure of the IGBT 1000 according to the tenth embodiment with the structure of the IGBT 1100 according to the eleventh embodiment.

In IGBT 1200 according to the embodiment, the n-type barrier layer 22 operates as a potential barrier to holes in the n⁻-type base layer 2 similar to the IGBT 1100 according to the eleventh embodiment. Consequently, in the IGBT 1200 according to the embodiment, holes are further accumulated in the n⁻-type base layer 2 compared with the IGBT 1000 according to the tenth embodiment. Therefore, the ON resistance of the IGBT 1200 according to the embodiment is further reduced. That is, interposing the n-type barrier layer 22 prevents holes from flowing to the emitter electrode 11 through the p⁺-type contact layer 20, and the reduction of the ON resistance can be realized compared with the sixth embodiment.

Although not shown, similar to the IGBTs according to the eighth and ninth embodiments, the IGBT 1200 according to the embodiment may include the conductor 21 provided in the third trench 3c via the insulating film 4c, the third trench 3c going through the p⁺-type contact layer 20 and the n-type barrier layer 22 from the surface of the p⁺-type contact layer 20 under the insulating film 9 and extending into the n⁻-type base layer 2.

Although not shown, the IGBTs according to the first to seventh embodiments also may include the n-type barrier layer 22 in the portion of the n-type barrier layer 22 sandwiched between the first p-type base layer 7a and the second p-type base layer 7b, similar to the IGBTs according to the ninth embodiment, the eleventh embodiment and the twelfth embodiment.

While various embodiments have been described, these embodiments may be combined with one another to change other embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An insulated gate bipolar transistor comprising:
a first semiconductor layer of a first conductivity type having a first surface and a second surface on an opposite side to the first surface;
a first trench extending from the first surface of the first semiconductor layer into the first semiconductor layer;
a second trench extending from the first surface of the first semiconductor layer into the first semiconductor layer and adjacent to the first trench;
a first base layer of a second conductivity type selectively formed on the first surface of the first semiconductor layer between the first trench and the second trench and exposed at a side wall of the first trench;
a second base layer of the second conductivity type selectively formed on the first surface of the first semiconductor layer between the first trench and the second trench, exposed at a side wall of the second trench and adjacent to the first base layer via the first semiconductor layer;
a first emitter layer of the first conductivity type selectively formed on a surface of the first base layer and exposed at the side wall of the first trench;
a second emitter layer of the first conductivity type selectively formed on a surface of the second base layer and exposed at the side wall of the second trench;
a first gate electrode provided on the first semiconductor layer, on the first base layer, and on the first emitter layer via a first gate insulating film in the first trench;
a second gate electrode provided on the first semiconductor layer, on the second base layer, and on the second emitter layer via a second gate insulating film in the second trench and electrically connected to the first gate electrode;
an interlayer insulating film provided on the first gate electrode and on the second gate electrode;
a second semiconductor layer of the second conductivity type provided on the second surface of the first semiconductor layer;
a first electrode electrically connected to the second semiconductor layer; and
a second electrode electrically connected to the first base layer, the second base layer, the first emitter layer, and the second emitter layer.

2. The transistor according to claim 1, further comprising a first insulating film provided on the first base layer and the second base layer, and covering the first surface in a portion of the first semiconductor layer sandwiched between the first base layer and the second base layer,
the second electrode being insulated from the first surface of the first semiconductor layer by the first insulating film.

3. The transistor according to claim 2, wherein the first trench, the second trench, the first base layer, and the second base layer have a striped structure extending in a first direction parallel to one another on the first surface of the first semiconductor layer.

4. The transistor according to claim 3, wherein
the first emitter layer extends in the first direction along the first trench and
the second emitter layer extends in the first direction along the second trench.

5. The transistor according to claim 4, wherein each of the first emitter layer and the second emitter layer has a striped structure of a single layer extending along the first direction.

6. The transistor according to claim 4, wherein each of the first emitter layer and the second emitter layer is formed of a plurality of portions away from one another along the first direction.

7. The transistor according to claim 4, further comprising a plurality of third base layers of the second conductivity type on the first surface of the first semiconductor layer, the third layers extending in a second direction orthogonal to the first direction to connect the first base layer and the second base layer.

8. The transistor according to claim 7, wherein
the first insulating film covers an entire region of the first surface of the first semiconductor layer surrounded by adjacent third base layers out of the third base layers, the first base layer, and the second base layer and
the second electrode is electrically connected onto the adjacent third base layers.

9. The transistor according to claim 8, further comprising a third emitter layer of the first conductivity type selectively formed on a surface of at least one of the adjacent third base layers and connecting the first emitter layer and the second emitter layer.

10. The transistor according to claim 9, wherein the second electrode is electrically connected onto the third emitter layer and the one of the third base layers on which the third emitter layer is formed.

11. The transistor according to claim 7, wherein the first insulating film is connected to the interlayer insulating film in the second direction.

12. The transistor according to claim 6, wherein the first insulating film extends in a striped configuration along the first direction.

13. The transistor according to claim 2, further comprising a conductor provided in a third trench via a second insulating film, the third trench extending into the first semiconductor layer from the first surface of the first semiconductor layer and extending in the first semiconductor layer along the first direction, between the first base layer and the second base layer,
the conductor being electrically connected to the second electrode.

14. The transistor according to claim 1, further comprising a contact layer of the second conductivity type provided on a portion of the first semiconductor layer sandwiched between the first base layer and the second base layer, and connected to the first base layer and the second base layer.

15. The transistor according to claim 14, wherein the second electrode is directly electrically connected to the contact layer on the contact layer.

16. The transistor according to claim 14, wherein the first trench, the second trench, the first base layer, the second base layer, the contact layer, the first emitter layer and the second emitter layer extend along a first direction parallel to the first surface of the first semiconductor layer.

17. The transistor according to claim 14, wherein
the first trench, the second trench, the first base layer, the second base layer and the contact layer extend along a first direction parallel to the first surface of the first semiconductor layer,
the first emitter layer and the second emitter layer extend along a second direction parallel to the first surface of the first semiconductor layer and perpendicular to the first direction to combine each other, and form a fourth emitter layer of the first conductivity.

18. The transistor according to claim 14, further comprising a conductor provided on the first semiconductor layer and the contact layer in a third trench via a second insulating film, the third trench going through the contact layer from a surface of the contact layer, extending into the portion of the first semiconductor layer sandwiched between the first base layer and the second base layer, and extending in the contact layer and the first semiconductor layer along the first direction,
the conductor being electrically connected to the second electrode.

19. The transistor according to claim 14, wherein the first semiconductor layer includes a barrier layer of the first conductivity type in the portion of the first semiconductor layer sandwiched between the first base layer and the second base layer, the barrier layer having a concentration of an impurity of the first conductivity type higher than a concentration of an impurity of the first conductivity type of the first semiconductor layer.

20. An insulated gate bipolar transistor comprising:
a first semiconductor layer of a first conductivity type having a first surface and a second surface on an opposite side to the first surface;
a first trench extending from the first surface of the first semiconductor layer into the first semiconductor layer;
a second trench extending from the first surface of the first semiconductor layer into the first semiconductor layer and adjacent to the first trench;
a first base layer of a second conductivity type selectively formed on the first surface of the first semiconductor layer between the first trench and the second trench and exposed at a side wall of the first trench;
a second base layer of the second conductivity type selectively formed on the first surface of the first semiconductor layer between the first trench and the second trench, exposed at a side wall of the second trench and adjacent to the first base layer via the first semiconductor layer;
a first emitter layer of the first conductivity type selectively formed on a surface of the first base layer and exposed at the side wall of the first trench;
a second emitter layer of the first conductivity type selectively formed on a surface of the second base layer and exposed at the side wall of the second trench;
a first gate electrode provided on the first semiconductor layer, on the first base layer, and on the first emitter layer via a first gate insulating film in the first trench;
a second gate electrode provided on the first semiconductor layer, on the second base layer, and on the second emitter layer via a second gate insulating film in the second trench and electrically connected to the first gate electrode;
an interlayer insulating film provided on the first gate electrode and on the second gate electrode;
a first insulating film provided on the first base layer and on the second base layer and covering the first surface of the first semiconductor layer between the first base layer and the second base layer;
a second semiconductor layer of the second conductivity type provided on the second surface of the first semiconductor layer;
a first electrode electrically connected to the second semiconductor layer; and
a second electrode electrically connected to the first base layer, the second base layer, the first emitter layer, and the second emitter layer and insulated from the first surface of the first semiconductor layer by the first insulating film,
the first trench, the second trench, the first base layer, and the second base layer having a striped structure extending in a first direction parallel to one another on the first surface of the first semiconductor layer,
the first emitter layer extending in the first direction along the first trench,
the second emitter layer extending in the first direction along the second trench,
each of the first emitter layer and the second emitter layer having a striped structure of a single layer extending along the first direction,
further comprising:
a plurality of third base layers of the second conductivity type provided on the first surface of the first semiconductor layer and extending in a second direction orthogonal to the first direction to connect the first base layer and the second base layer;
a third emitter layer of the first conductivity type selectively formed on a surface of at least one of adjacent third base layers out of the third base layers and connecting the first emitter layer and the second emitter layer,
a contact layer of the second conductivity type provided on a portion of the first semiconductor layer sandwiched between the first base layer and the second base layer, and connected to the first base layer and the second base layer; and
a conductor provided on the first semiconductor layer and the contact layer in a third trench via a second insulating film, the third trench going through the contact layer from a surface of the contact layer, extending into the portion of the first semiconductor layer sandwiched between the first base layer and the second base layer, and extending in the contact layer and the first semiconductor layer along the first direction, the conductor being electrically connected to the second electrode,
the first insulating film covering an entire region of the first surface of the first semiconductor layer surrounded by the adjacent third base layers, the first base layer, and the second base layer,
the second electrode being electrically connected onto the third emitter layer and the one of the third base layers on which the third emitter layer is formed,
the first semiconductor layer including a barrier layer of the first conductivity type in the portion of the first semiconductor layer sandwiched between the first base layer and the second base layer, the barrier layer having a concentration of an impurity of the first conductivity type higher than a concentration of an impurity of the first conductivity type of the first semiconductor layer.
